(19) United States
(12) Patent Application Publication
(10) Pub. No.: US 2011/0243520 A1
(43) Pub. Date: Oct. 6, 2011

(54) OPTICAL WAVEGUIDE STRUCTURE AND METHOD OF MANUFACTURE THEREOF

(76) Inventors: Gayle Murdoch, Darlington (GB); Matthew Francis O'Keefe, County Durham (GB); Stephen John Clements, Essex (GB)

(21) Appl. No.: 12/671,558

(22) PCT Filed: Jul. 10, 2008
(86) PCT No.: PCT/GB08/02376

§ 371 Date: Jun. 20, 2011

(30) Foreign Application Priority Data
Jul. 31, 2007 (GB) 0714809.1

(51) Int. Cl. G02B 6/136; H01L 21/302

(52) U.S. Cl. 385/131; 438/706; 257/E21.214

(57) ABSTRACT

An optical waveguide structure including a III-V semiconductor substrate, a III-V semiconductor top layer, and an etch stop layer sandwiched therebetween, the etch stop layer containing aluminium and phosphorous, the top layer including first and second spaced apart recesses extending through the top layer to the etch stop layer and defining an optical waveguide therebetween. Also a method of manufacture of an optical waveguide structure including the steps of: providing a multilayer semiconductor wafer including a III-V semiconductor substrate, a III-V semiconductor top layer and an etch stop layer sandwiched therebetween, the etch stop layer including aluminium and phosphorous; and etching through the top layer to the etch stop layer by use of a dry etch containing chlorine to provide two spaced apart recesses defining the optical waveguide therebetween.

The present invention relates to an optical waveguide structure and method of manufacture thereof. More particularly, but not exclusively, the present invention relates to an optical waveguide structure comprising an etch stop layer comprising Al and P sandwiched between two III-V semiconductor layers, one of the III-V layers comprising at least two recesses which between them define the optical waveguide.

It is known to manufacture optical waveguide structures from substrates of GaAs or AlGaAs. Typically, this is done by etching two spaced apart recesses in the substrate to define a waveguide therebetween. Wet etching is often used for such devices however for large substrates this produces uneven etching results. Dry etching is to be preferred. To get good control of etched features in dry etching it is normal to arrange for a degree of directionality in the etching so that verticality of the etched feature is maintained. However the conditions for getting verticality are usually in conflict with the desire to have selectivity between layers of different composition. For instance it is normal to have low selectivity in the dry etching of GaAs and AlGaAs and for extremely vertical features in multilayer structures it is actually desirable to have no selectivity. Control of etch depth is therefore not straightforward to any degree of precision At present when dry etching is used control is limited to end point detectors or timed etching which limits control. Typical depth control under well-controlled etch conditions might be as little as a few percent across and between wafers, yet many optical structures require better control than this and ideally would be limited only by the thickness control of individual layers.

Accordingly, in a first aspect, the present invention provides an optical waveguide structure comprising

a III-V semiconductor substrate;

a III-V semiconductor top layer; and,

an etch stop layer sandwiched therebetween, the etch stop layer containing Aluminium and Phosphorous;

the top layer comprising first and second spaced apart recesses extending through the top layer to the etch stop layer and defining an optical waveguide therebetween.

The optical waveguide structure according to the invention can be manufactured using a dry chlorine based etch. The selectivity of the etch is such that, to first order, etching stops when the etch reaches the etch stop layer. This reduces variation across the substrate as in regions where the etch has reached the etch stop etching will stop whilst in other parts of the substrate it can continue until the etch stop is reached.

In addition, the position of the etch stop layer can be set accurately during the epitaxial process allowing the dimensions of the waveguide to be set accurately.

Preferably, the etch stop layer comprises at least one of an AlInP or AlGaP layer.

The optical etch stop layer can comprise an AlInP layer.

The composition of the AlInP etch stop layer can be AlₓIn₁₋ₓP, where x is in the range 0.05 to 0.95, preferably in the range 0.4 to 0.6, more preferably 0.5

The etch stop layer can comprise an AlGaP layer.

The etch stop layer can comprise both AlInP and AlGaP layers.

The top layer can comprise a GaAs layer.

The top layer can comprise a AlGaAs layer.

The composition of the AlGaAs top layer can be Al_{y}Ga_{1-y}As, where y is in the range 0.1 to 0.95, more preferably in the range 0.2 to 0.35, more preferably 0.24.

The top layer can comprise a plurality of III-V semiconductor layers.

The top layer can comprise a plurality of AlGaAs layers.

The top layer can comprise a plurality of GaAs layers.

Preferably, each of the semiconductor layers of the top layer is a composition which may be selectively etched with respect to the etch stop layer by a chlorine containing dry etchant.

The substrate can comprise a GaAs layer.

The substrate can comprise an AlGaAs layer.

The composition of the AlGaAs substrate layer can be Al_{z}Ga_{1-z}As, where z is in the range 0.1 to 0.95, preferably in the range 0.2 to 0.35, more preferably 0.24.

The substrate can comprise a plurality of III-V semiconductor layers.

The substrate can comprise a plurality of AlGaAs layers.

The substrate can comprise a plurality of GaAs layers.

In a further aspect of the invention there is provided a method of manufacture of an optical waveguide structure comprising the steps of

providing a multilayer semiconductor wafer comprising a III-V semiconductor substrate, a III-V semiconductor top layer and an etch stop layer sandwiched therebetween, the etch stop layer comprising aluminium and phosphorous; and

etching through the top layer to the etch stop layer by use of a dry etch containing chlorine to provide two spaced apart recesses defining the optical waveguide therebetween.

The III-V semiconductor top layer can comprise a plurality of III-V semiconductor layers.

The III-V semiconductor top layer can comprises at least one GaAs layer.

The III-V semiconductor top layer can comprise at least one AlGaAs layer, the AlGaAs layer preferably having the composition Al_{z}Ga_{1-z}As where z is in the range 0.1 to 0.95, more preferably in the range 0.2 to 0.35, more preferably 0.24

The dry etch can be a chlorine containing precursor.

The chlorine containing precursor can comprise chlorine gas.

The chlorine containing precursor can comprise BCl₃.

The chlorine containing precursor can comprise CCl₄.

In a further aspect of the invention there is provided an optical device comprising an optical waveguide structure the optical waveguide structure comprising

a III-V semiconductor substrate;

a III-V semiconductor top layer; and,

an etch stop layer sandwiched therebetween, the etch stop layer containing Aluminium and Phosphorous;

the top layer comprising first and second spaced apart recesses extending through the top layer to the etch stop layer and defining an optical waveguide therebetween.

The present invention will now be described by way of example only, and not in any limitative sense, with reference to the accompanying drawing in which

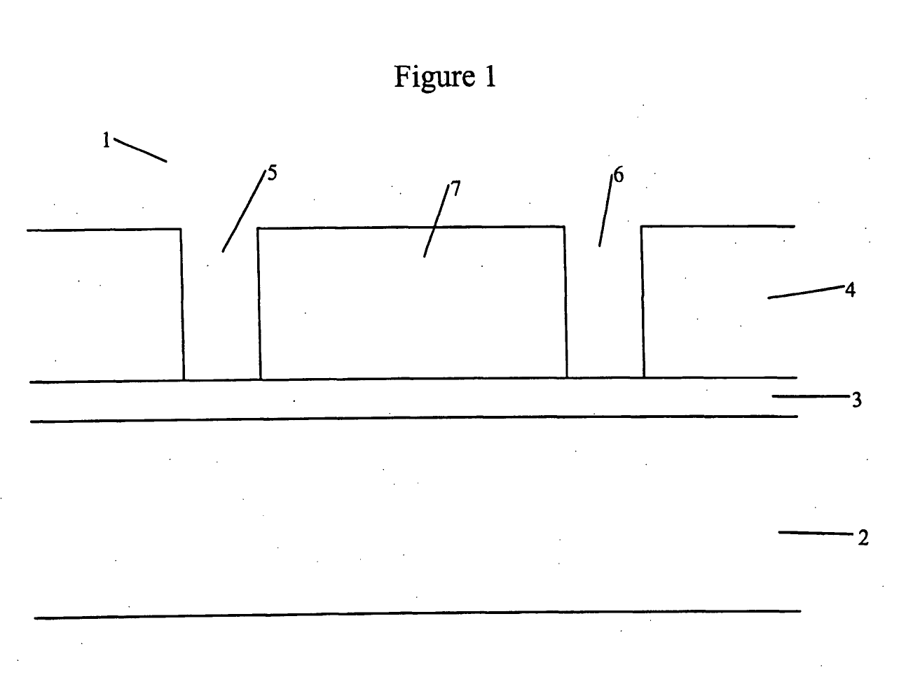

FIG. 1 shows a first embodiment of an optical waveguide structure according to the invention in cross section;

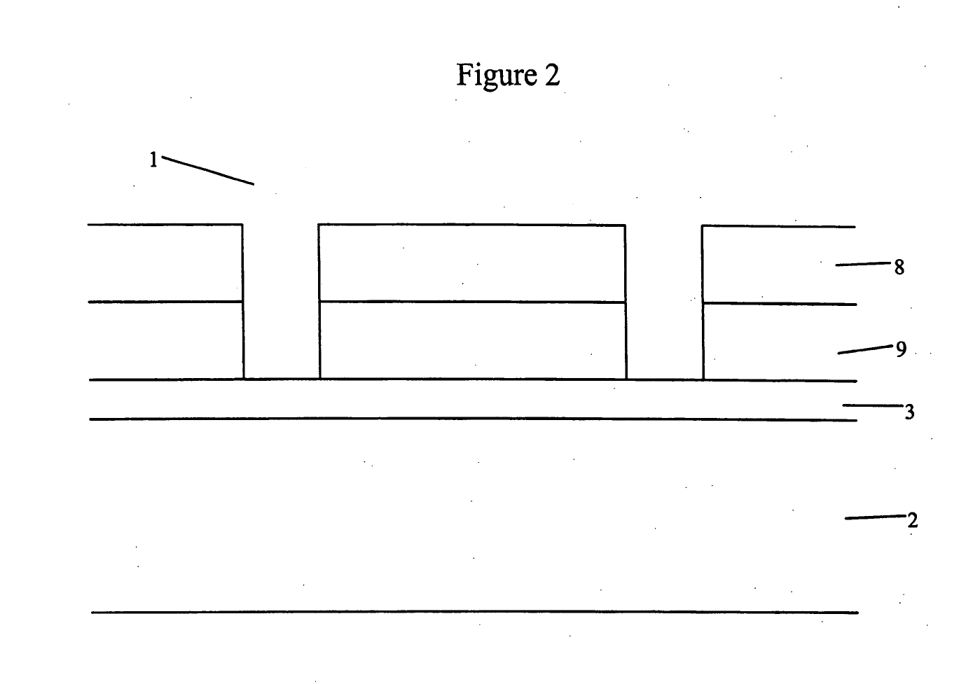

FIG. 2 shows second embodiment of an optical waveguide structure according to the invention in cross section; and,

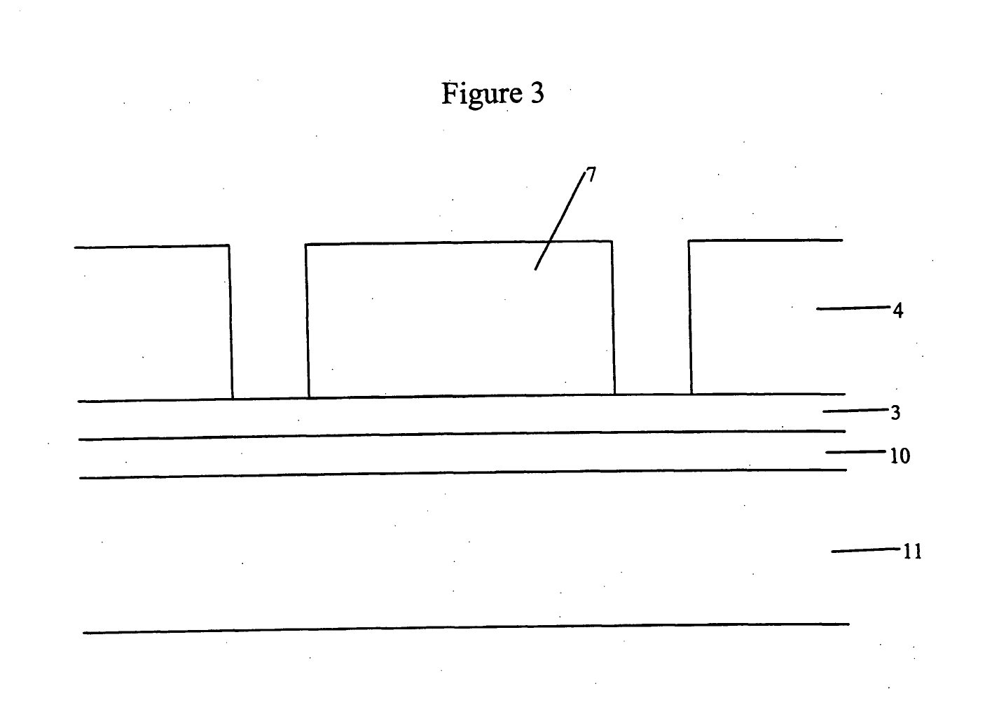

FIG. 3 shows a third embodiment of an optical waveguide structure according to the invention.

Semiconductor optical waveguide structures are formed by etching spaced apart trenches in a semiconductor layer so defining the optical waveguide therebetween. The performance of the waveguide depends strongly on the etch depth. Typically this controls the waveguiding and can effect its loss, ability to couple light to different structures within the waveguide device or to couple light out to an adjoining structure (for example a fibre).

Often this is achieved by wet etching. However, particularly on large substrates, wet etching produces variation in profile across the substrate, with consequent variation in waveguide performance across the substrate.

An alternative to wet etching is dry etching. This reduces variation in etch depth across the substrate, but it is difficult to get good profile control combined with any amount of selectivity between layers of different composition. At present, current methods of dry etching are limited to the use of end point detectors or timed etching resulting in poor depth control.

Shown in FIG. 1 is an optical waveguide structure 1 according to the invention. The waveguide structure 1 comprises a III-V semiconductor substrate 2. In this embodiment the substrate 2 is GaAs. Arranged on the substrate 2 is an etch stop layer 3 comprising both Aluminium and Phosphorous. In this embodiment the etch stop layer 3 is Al_{0.5}In_{0.5}P. Arranged on the etch stop layer 3 is a top layer 4 comprising a III-V semiconductor. In this embodiment the top layer 4 is GaAs.

Extending through the top layer 4 to the etch stop layer 3 are first and second spaced apart recesses 5,6. The top layer 4 between the recesses 5,6 defines an optical waveguide 7.

The optical waveguide structure 1 according to the invention is manufactured by providing a mask (not shown) on the top layer 4. The mask comprises recesses extending through the mask to the top layer 4. The top layer 4 is etched by a chlorine based dry etch through the apertures 5,6 in the mask down to the etch stop layer 3 to define the waveguide 7. In this embodiment the etch is chlorine gas.

The use of a dry etch with an etch stop layer 3 improves the uniformity of etch depth. To first order etching stops when the etchant reaches the etch stop layer 3. Accordingly, variation in etch rate across the substrate 2 can be virtually eliminated by leaving the etch in contact with the top layer 4 until it has reached the etch stop layer 3 across the substrate 2. The position of the etch stop layer 3 can be set accurately during the epitaxial growth of the composite structure comprising the substrate 2, etch stop layer 3 and top layer 4. This combination of factors allows for a high degree of control of the shape of the optical waveguide 7 with a large degree of uniformity across the substrate 2. This increases the yield of optical waveguide structures 1 having acceptable performance characteristics when manufactured by a route involving etching so reducing manufacturing costs. It is also possible improve device performance using such waveguides or even enable the manufacture of devices which would not otherwise be possible without such depth control.

The composition of the etch stop layer 3 of the above embodiment is Al_{0.5}In_{0.5}P. Other compositions are possible. More generally the composition is AlₓIn₁₋ₓP with x in the range 0.05 to 0.95, more preferably in the range 0.4 to 0.6. An alternative etch stop layer is AlGaP.

It is also possible to obtain further levels of etch depth control by using optical emission spectroscopy to identify when the etch has reached the etch stop layer. When this method is employed it is preferred to use AlInP, rather than AlGaPas the etch stop layer 3 as the absence of Gallium can be monitored in the received signal to indicate that the etch stop layer 3 has been reached. In this way a controlled level of overetching can be carried out to ensure that the etch has run to completion across the wafer, where, because of the range of feature size or type, the etch time can vary slightly. Because of the high level of etch selectiyity it is then possible to ensure that the whole wafer has been etched to the same layer with a high degree of precision.

Alternatives to GaAs for the substrate 2 are also possible. Any III-V semiconductor layer which can be selectively etched with respect to an etch stop layer 3 comprising Aluminium and Phosphorous can be suitable. A preferred alternative is Al_{z}Ga_{1-z}As with z in the range 0.1 to 0.95, more preferably in the range 0.2 to 0.35, preferably 0.24.

Similarly, alternatives to GaAs for the top layer 4 are also possible. A preferred alternative is Al_{y}Ga_{1-y}As with y in the range 0.05 to 0.95, preferably in the range 0.4 to 0.6, more preferably 0.5.

In the above embodiments the top layer 4 and substrate 2 are single layers. In alternative embodiments either or both of the top layer 4 and substrate 2 can comprise a plurality of III-V semiconductor layers.

Shown in FIG. 2 is a further embodiment of an optical waveguide structure 1 according to the invention. In this embodiment the semiconductor top layer 4 comprises an AlGaAs layer 8 and a GaAs layer 9. In alternative embodiments (not shown) the top layer 4 can comprise a plurality of AlGaAs and/or GaAs layers.

Shown in FIG. 3 is a further embodiment of an optical waveguide structure 1 according to the invention. The refractive index of AlInP is less than that of AlGaAs which is in turn less than that of GaAs. Ideally, one would like the refractive index of the material of the optical waveguide 7 to be matched to that of the layers on which it stands. In this embodiment the top layer 4 is AlGaAs, the etch stop layer 3 is AlInP (or possibly AlGaP) and the immediate underlying layer 10 is GaAs. By arranging the thicknesses of the etch stop and underlying layers 3, 10 correctly these layers 3,10 can provide an effective refractive index which matches that of the AlGaAs waveguide 7. Typical preferred thicknesses are 20 nanometres for the etch stop layer 3 and 40 nanometres for the underlying GaAs layer 10.

A range of possible chlorine based dry etch chemistries are possible. Typically the dry etch is a chlorine containing precursor. The etch can be chlorine gas. Alternatively the etch can be BCl₃. In a further alternative the etch can be CCl₄. The etch technique can utilise reactive ion etching, downstream plasma etching, inductively coupled plasmas and other dry etch techniques commonly used in optical device fabrication.

A specific example of etch conditions is set out in table 1 below. The breakthrough step is designed to ignite the plasma and remove any native oxide from the substrate surface.

The main etch should have a low etch rate but to be anisotropic it requires a reasonably high bias power. This means that the etch is a balance between bombardment etching and chemical etching and thus the etch rate must be controlled by the ratio of BCl₃ to Cl₂. Selectivity is also controlled by the gas ratio.

The process is monitored by using the Ga 417 nm line with an optical EPD system. Once the intensity of Ga drops endpoint is reached. High selectivity ensures that an over etch can be performed to ensure removal of all AlGaAs due to non-uniformity of etch rate.

This process improves the etch depth uniformity from around 5% to less than 2%.

In a further embodiment of the invention the etch stop layer 3 comprises a plurality of layers comprising Aluminium and Phosphorous.

Such an optical waveguide structure can be employed in a variety of optical devices.

1. An optical waveguide structure comprising
a III-V semiconductor substrate;
a III-V semiconductor top layer; and,
an etch stop layer sandwiched therebetween, the etch stop layer containing Aluminium and Phosphorous;
the top layer comprising first and second spaced apart recesses extending through the top layer to the etch stop layer and defining an optical waveguide therebetween.

2. An optical waveguide structure as claimed in claim 1, wherein the etch stop layer comprises at least one of an AlInP or AlGaP layer.

3. An optical waveguide structure as claimed in claim 2, wherein the optical etch stop layer comprises an AlInP layer.

4. An optical waveguide structure as claimed in claim 3, wherein the composition of the AlInP layer is AlₓIn₁₋ₓP, where x is in the range 0.05 to 0.95.

5. An optical waveguide structure as claimed in claim 2, wherein the etch stop layer comprises an AlGaP layer.

6. An optical waveguide structure as claimed in claim 2, wherein the etch stop layer comprises both AllnP and AlGaP layers.

7. An optical waveguide structure as claimed in claim 1, wherein the top layer comprises a GaAs layer.

8. An optical waveguide structure as claimed in claim 1, wherein the top layer comprises a AlGaAs layer.

9. An optical waveguide structure as claimed in claim 8, wherein the composition of the AlGaAs layer is Al_{y}Ga_{1-y}As, where y is in the range 0.1 to 0.95.

10. An optical waveguide structure as claimed in claim 1, any wherein the top layer comprises a plurality of III-V semiconductor layers.

11. An optical waveguide structure as claimed in claim 10, wherein the top layer comprises a plurality of AlGaAs layers.

12. An optical waveguide structure as claimed in claim 10, wherein the top layer comprises a plurality of GaAs layers.

13. An optical waveguide structure as claimed in claim 10 wherein each of the semiconductor layers of the top layer is a composition which may be selectively etched with respect to the etch stop layer by a chlorine containing dry etchant.

14. An optical waveguide structure as claimed in claim 1, wherein the substrate comprises a GaAs layer.

15. An optical waveguide structure as claimed in claim 1, wherein the substrate comprises an AlGaAs layer.

16. An optical waveguide structure as claimed in claim 15, wherein the composition of the AlGaAs layer is Al₂Ga_{1-z}As, where z is in the range 0.1 to 0.95.

17. An optical waveguide structure as claimed in claim 1, wherein the substrate comprises a plurality of III-V semiconductor layers.

18. An optical waveguide structure as claimed in claim 17, wherein the substrate comprises a plurality of AlGaAs layers.

19. An optical waveguide structure as claimed in claim 17, wherein the substrate comprises a plurality of GaAs layers.

20. A method of manufacture of an optical waveguide structure comprising the steps of
providing a multilayer semiconductor wafer comprising a III-V semiconductor substrate, a III-V semiconductor top layer and an etch stop layer sandwiched therebetween, the etch stop layer comprising aluminium and phosphorous; and
etching through the top layer to the etch stop layer by use of a dry etch containing chlorine to provide two spaced apart recesses defining the optical waveguide therebetween.

21. A method as claimed in claim 20 wherein the III-V semiconductor top layer comprises a plurality of III-V semiconductor layers.

22. A method as claimed in claim 20, wherein the III-V semiconductor top layer comprises at least one GaAs layer.

23. A method as claimed in claim 20, wherein the semiconductor top layer comprises at least one AlGaAs layer, the AlGaAs layer preferably having the composition Al_{z}Ga_{1-z}As where z is in the range 0.1 to 0.95.

24. A method as claimed in claim 20, wherein the dry etch is a chlorine containing precursor.

25. A method as claimed in claim 24 wherein the chlorine containing precursor comprises chlorine gas.

26. A method as claimed in claim 24, wherein the chlorine containing precursor comprises BCl₃.

27. A method as claimed in claim 24, wherein the chlorine containing precursor comprises CCl₄.

28. An optical device comprising an optical waveguide structure as claimed in claim 1.

29-31. (canceled)

32. An optical waveguide structure as claimed in claim 4, wherein x is in the range of about 0.4 to about 0.6.

33. An optical waveguide structure as claimed in claim 32, wherein x is about 0.5.

34. An optical waveguide structure as claimed in claim 9, wherein y is in the range of about 0.2 to about 0.35.

35. An optical waveguide structure as claimed in claim 34, wherein y is about 0.24.

36. An optical waveguide structure as claimed in claim 16, wherein z is in the range of about 0.2 to about 0.35.

37. An optical waveguide structure as claimed in claim 36, wherein z is about 0.24.

38. A method as claimed in claim 23, wherein z is in the range of about 0.2 to about 0.35.

39. A method as claimed in claim 38, wherein z is about 0.24.
